(19) United States
(12) Patent Application Publication
(10) Pub. No.: US 2014/0261609 A1
(43) Pub. Date: Sep. 18, 2014

(54) ULTRATHIN NANOWIRE-BASED AND NANOSCALE HETEROSTRUCTURE BASED THERMOELECTRONIC CONVERSION STRUCTURES AND METHOD OF MAKING THE SAME

(71) Applicant: PURDUE RESEARCH FOUNDATION, West Lafayette, IN (US)

(72) Inventors: Yue Wu, West Lafayette, IN (US); Genqiang Zhang, West Lafayette, IN (US)

(73) Assignee: PURDUE RESEARCH FOUNDATION, West Lafayette, IN (US)

(21) Appl. No.: 14/167,653

(22) Filed: Jan. 29, 2014

Related U.S. Application Data
(63) Continuation-in-part of application No. 13/642,992, filed on Oct. 23, 2012.
(60) Provisional application No. 61/758,254, filed on Jan. 29, 2013.

(51) Int. Cl. H01L 35/16

(52) U.S. Cl. CPC H01L 35/16
USPC 136/238

(57) ABSTRACT

A nano scale hetero structure tellurium-based nanowire structure is disclosed including a dumbbell-like crystalline heterostructure having a center rod-like portion and one octahedral structure connected to each end of each of the center rod-like portions, wherein the center rod-like portion is a bismuth-telluride nanowire structure and the octahedral structures are lead telluride.

### PRIORITY

The present application is related to, and claims the priority benefit of, U.S. Provisional Patent Application Ser. No. 61/758,254, filed Jan. 29, 2013. The present application is a continuation-in-part of U.S. patent application Ser. No. 13/642,992, filed Oct. 23, 2012, which claims the priority benefit of, and is a U.S. §371 national stage entry of, International Patent Application Serial No. PCT/US2011/033798, filed Apr. 25, 2011, which is related to, and claims the priority benefit of U.S. Provisional Application Ser. Nos. 61/327,192 and 61/327,199, both filed Apr. 23, 2010. The contents of each of these applications are hereby incorporated by reference in their entirety into this disclosure.

### GOVERNMENT LICENSE RIGHTS

This invention was made with government support under FA9550-12-1-0061 awarded by United States Air Force Office of Scientific Research (USAF/AFOSR). The government has certain rights in the invention.

### TECHNICAL FIELD

The present disclosure generally relates to material suitable for thermoelectric conversion and particularly to material with nanowire-based and nanoscale heterostructure-based structures and processes of making same.

### BACKGROUND

In the modern world, production of thermal energy is a byproduct of almost every activity. Examples are operating internal combustion engines, lighting incandescent light bulbs, operating power plants, etc. Currently, most of the produced thermal energy is lost, as is thereby considered wasted. It would be beneficial to reclaim some or most of the thermal energy and convert it to a useful form of energy.

Thermoelectric devices provide one way to convert thermal energy into electrical energy. A thermoelectric device positioned between a hot reservoir and a cold reservoir can convert the thermal difference between these reservoirs into an electrical current. The reversal of this process, i.e., application of an electrical current to a thermoelectric device, may be used to transfer heat from a first body to a second body, thereby cooling the first body. Referring to FIG. 16, a schematic of an application of prior art use of thermoelectric material is depicted.

The mechanism by which thermal energy is converted to electrical current is commonly referred to as the Seebeck effect. The Seebeck effect can be explained as follows. A thermal gradient at a junction of two dissimilar materials, ΔT=T_{H}−T_{C} (see FIG. 4), can generate a voltage ΔV due to the Seebeck effect. The generated voltage is governed by

$$S = \frac{Δ V}{Δ T} \qquad ( 1 )$$

where S is Seebeck coefficient,

ΔV is the generated voltage; and

ΔT is the thermal gradient. Whether the Seebeck coefficient is a positive or negative number depends on whether the carriers are holes or electrons. The higher the Seebeck coefficient the higher voltage AV is generated for the same thermal gradient ΔT.

Figure of Merit is one way to measure the efficiency of the thermoelectric material and structure. Figure of Merit is denoted as ZT and is expressed as

$$Z T = \frac{{S}^{2} σ}{κ} T \qquad ( 2 )$$

where S is the Seebeck coefficient,

σ is the electrical conductivity,

κ is thermal conductivity, and

T is the temperature. As apparent from (2), to achieve a high figure of merit, the thermoelectric material requires a low thermal conductivity and a high electrical conductivity. Low thermal conductivity slows heat transfer from the hot body to the cold body. The high electrical conductivity lowers electrical losses due to electrical resistance

Different structures have been investigated by others in the prior art to improve the Figure of Merit for different thermoelectric materials. Examples of the thermoelectric materials are Bismuth telluride (Bi₂Te₃), and lead telluride (PbTe).

There is a need to provide material selection, structure and method of making same that improves efficiency of thermoelectric conversion.

### SUMMARY

According to one aspect of the present disclosure an ultrathin tellurium nanowire structure is disclosed. The nanowire structure includes a rod-like crystalline structure of tellurium, wherein the crystalline structure is defined by diameters of between 5-6 nm.

According to another aspect of the present disclosure an ultrathin tellurium-based nanowire structure is disclosed. The nanowire structure includes a rod-like crystalline structure of one of lead telluride and bismuth telluride, wherein an ultrathin tellurium nanowire structure is used as a precursor to generate the rod-like crystalline structure.

According to another aspect of the present disclosure, a nano scale hetero structure tellurium-based nanowire structure is disclosed. The nanowire structure includes a dumbbell-like crystalline heterostructure having a center rod-like portion and one octahedral structure connected to each end of each of the center rod-like portions, wherein the center rod-like portion is a bismuth telluride nanowire structure and the octahedral structures are lead telluride.

### BRIEF DESCRIPTION OF THE DRAWINGS

FIGS. 1A and 1B are transmission electron microscopy (TEM) images of ultrathin tellurium nanowire structures with average diameters of about 5.5±0.5 nm depicted at different scales (A at 200 nm and B at 10 nm).

FIGS. 2A and 2B are TEM images of ultrathin lead telluride nanowire structures at different scales (A at 100 nm and B at 20 nm).

FIGS. 2C and 2D are TEM images of ultrathin bismuth telluride nanowire structures after injecting lead acetate and bismuth nitrate pentahydrate precursor solution into a tellurium nanowire solution at different scales (C at 100 nm and D at 20 nm).

FIG. 3 is X-ray diffraction patterns of tellurium, lead telluride and bismuth telluride nanowire structures.

FIGS. 4A and 4B are TEM images of tellurium nanowire structures with diameters of about 20 nm and lengths ranging from 1.2 to 1.5 micrometers depicted at different magnifications (A at 200 nm and B at 20 nm).

FIG. 5 is an X-ray diffraction pattern of the tellurium nanowire structures.

FIGS. 6A and 6B are TEM images of tellurium-lead telluride dumbbell-like hetero structure nanowire structures at different magnifications (A at 200 nm and B at 50 nm).

FIG. 7 is an X-ray diffraction pattern of the synthesized tellurium-lead telluride dumbbell-like hetero structure nanowire structures.

FIGS. 8A and 8B are TEM images of cadmium telluride-lead telluride dumbbell-like hetero structure nanowire structures at different magnifications (A at 500 nm and B at 100 nm).

FIG. 9 is an X-ray diffraction pattern of cadmium telluride-lead telluride dumbbell-like hetero structure nanowire structures.

FIGS. 10A and 10B are TEM images of bismuth telluride-lead telluride dumbbell-like heterostructure nanowire structure at different magnifications (A at 500 nm and B at 200 nm).

FIG. 11 is an X-ray diffraction pattern of bismuth telluride-lead telluride dumbbell-like hetero structure nanowire structures.

FIG. 12 is a plot of conductivity vs. temperature for lead telluride nanowire bulk sample compressed by spark plasma sintering.

FIG. 13 is a plot of Seebeck coefficient for lead telluride nanowire bulk sample compressed by plasma sintering.

FIG. 14 is a plot of Scaled amplitude vs. frequency at room temperature for lead telluride nanowire bulk sample compressed by spark plasma sintering.

FIG. 15 is a plot of thermoelectric figure of merit (ZT) vs. temperature for various samples.

FIG. 16 is a schematic of an application of prior art use of thermoelectric material.

FIG. 17 is X-ray diffraction patterns of synthesized bismuth telluride-lead telluride dumbbell-like heterostructure nanowire structures.

FIG. 18 is a schematic of the synthesis process of bismuth telluride-lead telluride dumbbell-like heterostructure nanowire structures.

### DETAILED DESCRIPTION

For the purposes of promoting an understanding of the principles of the present disclosure, reference will now be made to the embodiments illustrated in the drawings and described in the following written specification. It is understood that no limitation to the scope of the present disclosure is thereby intended. It is further understood that the present disclosure includes any alterations and modifications to the illustrated embodiments and includes further applications as would normally occur to one of ordinary skill in the art to which this disclosure pertains.

The present disclosure provides novel approaches to generate novel ultrathin nanowire-based structures as well as nanoscale hetero structure-based structures for use as material to be used in thermoelectric conversion. First, a novel process is described to generate a novel ultrathin nanowire structure. Second, a novel process is described to generate novel nanoscale hetero structure-based structures.

### Ultrathin Nanowire-Based Structures

The present disclosure provides an efficient process for synthesis of ultrathin lead telluride (PbTe) and Bismuth telluride (Bi₂Te₃) nanowire structures. The process described generates novel nanowire structures with diameters of about or less than 10 nm. The process includes utilizing ultrathin tellurium (Te) nanowire structures as in-situ templates. Phase transfer from Te to PbTe or to BiₓTe₁₋ₓ is accomplished through injection of lead (Pb) or bismuth (Bi) precursor solutions to a solution containing Te nanowire.

The synthesized PbTe and Bi₂Te₃ ultrathin nanowire structures are fabricated through a two-step process. First, the Te nanowire structures are synthesized to be used as in-situ templates.

### Synthesis of Ultrathin Te Nanowire Structures

In a typical synthesis, a volume of ethylene glycol (CH₂OHCH₂OH), e.g., 10 ml, an amount of polyvinylpyrrolidone (PVP), e.g., 0.1-1 g, an amount of an alkali (sodium hydroxide (NaOH) or potassium hydroxide (KOH)), e.g., 0.2-0.8 g, and an amount of tellurium dioxide (TeO₂) or tellurite salts (sodium tellurite (Na₂TeO₃), or potassium tellurite (K₂TeO₃)), e.g., 0.2-2 mmol, are dissolved in ethylene glycol by heating to form a transparent/translucent solution. Next, an amount of hydrazine hydrate (H₂NNH₂.H₂O) solution, e.g., 0.2-1 ml, is added into the as-prepared solution at 100-180° C. The concentration of hydrazine can be between 24-100%, After about 20 minutes, ultrathin Te nanowire structures with average diameters of 5.5±0.5 nm and lengths up to several micrometers can be obtained. Referring to FIGS. 1A and 1B transmission electron microscopy (TEM) images of ultrathin tellurium nanowire crystalline structures with average diameters of about 5.5±0.5 nm are depicted at different scales (A at 200 nm and B at 10 nm).

### Synthesis of Ultrathin Metal Telluride Nanowire Structures

Using the synthesized ultrathin Te nanowire structures as in-situ templates, metal telluride nanowire structures can be produced by injecting associated metal precursors into the solution containing Te nanowire structures. The PbTe nanowire crystalline structures with diameters of 9.5±0.5 nm and Biₓ Te₁₋ₓ nanowire crystalline structures with diameters of 7.5±0.5 nm can be obtained by injecting lead acetate tri-hydrate (Pb(CH₃COO)₂.3H₂O) and bismuth nitrate penta-hydrate (Bi(NO₃)₃.5H₂O) in ethylene glycol precursor solution, respectively and allowing the solution to react for about 30 minutes. The quantity of the injected metal precursor is calculated according to the molar ratio of elements in corresponding compounds. Referring to FIGS. 2A and 2B, TEM images of ultrathin lead telluride nanowire structures at different scales (A at 100 nm and B at 20 nm) are depicted. Referring to FIGS. 2C and 2D, TEM images of ultrathin bismuth telluride nanowire structures after injecting lead acetate and bismuth nitrate pentahydrate precursor solution into a tellurium nanowire solution at different scales (C at 100 nm and D at 20 nm) are depicted.

To verify the phase transfer from Te to PbTe or Bi₂Te₃ nanowire structures, X-ray diffraction patterns of these three materials were obtained. Referring to FIG. 3, X-ray diffraction patterns of tellurium, lead telluride and bismuth telluride nanowire structures are depicted. As can be seen in FIG. 3, the nanowire structures can be indexed to pure Te, PbTe and Bi₂Te₃, respectively, indicating the formation of PbTe and Bi₂Te₃ after the injection of the Pb or Bi precursor solution.

PbTe and Bi₂Te₃ are well suited candidates for thermoelectric conversion at a temperature of about room temperature and 500° K, respectively. By fabricating novel nanowire structure with diameters less than 10 nm, the thermal conductivity can be significantly reduced to enhance the thermoelectric figure of merits by increasing the Seebeck coefficient. It should be understood that the solution phase method, described above, is easily scalable and reproducible for large-scale deployment of thermoelectric conversion devices.

The synthesized nanowire structures are uniform and crystalline with diameters less than 10 nm (e.g., PbTe having diameters of about 9.5±0.5 nm; and Bi₂Te₃ having diameters of about 7.5±0.5 nm) and lengths up to several micrometers. In addition, both PbTe and Bi₂Te₃ nanowire structures possess rough surfaces. These properties contribute to reduce the thermal conductivity of these materials as compared to corresponding bulk material. Also, the exact formation of the PbTe and Bi₂Te₃ nanowire structures can be controlled by adjusting the molar ratio between the Pb or Bi precursor and TeO₂. This feature may help to determine the most efficient material systems for the application of thermoelectric devices. It should be understood that the disclosed process can also be used to synthesize other metal telluride nanowire structures by simply changing the precursor solutions.

### Synthesis of Nanoscale Hetero Structure-Based Structures

The present disclosure describes process steps resulting in synthesis of novel nano scale hetero structure-based structures suitable for thermoelectric conversion. The process describes use of an ethylene glycol based solution for synthesizing three novel dumbbell-like nanowire heterostructures. These structures are based on tellurium-lead telluride (Te—PbTe), cadmium telluride-lead telluride (CdTe—PbTe) and bismuth telluride-lead telluride (Bi₂Te₃—PbTe) compositions. First, well-defined Te nanowire structures with diameters of about 20 nm are developed. Thereafter, a Pb precursor solution is injected into the solution containing Te nanowire structures. As a result, PbTe octahedral structures are selectively grown at both ends of the Te nanowire structures to form Te—PbTe dumbbell-like structures. In order to obtain CdTe—PbTe and Bi₂Te₃—PbTe dumbbell-like structure, a cadmium (Cd) precursor or a bismuth (Bi) precursor solution is injected to the Te—PbTe heterostructure nanowire solution, respectively. The center Te portion reacts with the reduced Cd or Bi atoms to form CdTe or Bi₂Te₃ nanowire structures, and then the CdTe—PbTe and Bi₂Te₃—PbTe part can be obtained.

### Te Nanowire Synthesis Structure

The process for synthesizing Te nanowire structures is similar to the process of synthesizing ultrathin nanowire structures, described above. However, one difference is at the end of the nanowire synthesis process, after adding the hydrazine hydrate solution at 100-180° C., the resulting solution is allowed to sit for about 20 minutes to one hour. The Te nanowire structures obtained have average diameters of about 20±2 nm and lengths ranging from 1.2 to 1.5 micrometers. Referring to FIGS. 4A and 4B TEM images of tellurium nanowire structures with diameters of about 20 nm and lengths ranging from 1.2 to 1.5 micrometers are depicted at different magnifications (A at 200 nm and B at 20 nm). Also, referring to FIG. 5 an X-ray diffraction pattern of the tellurium nanowire structures is provided. The X-ray diffraction pattern confirms the formation of pure hexagonal Te phase, as depicted in FIG. 5, which can be indexed according to Joint Committee on Powder Diffraction Standards (JCPDS) No. 79-0736. As depicted, the well-defined Te nanowire structures can be used as the in-situ templates for the growth of dumbbell-like heterostructure nanowire structures.

### Synthesis of Dumbbell-Like Heterostructure Nanowire Structures

To produce PbTe—Bi₂Te₃ nanowire heterostructures involves a three-step solution-phase reaction at a much lower temperature compared to the solid-state reactions. The reaction starts with the synthesis of Te nanowires as described above, followed by growth of Bi₂Te₃ nanoplates on the Te nanowire heads, then ended with the conversion of Te bodies in the Te—Bi₂Te₃ nanowire heterostructures into PbTe. The final structure looks like a ‘barbell’ of which the bar part is the PbTe nanowires and the “bells” are the Bi₂Te₃ nanoplates. Then, the as-synthesized products are washed with deionized water and alcohol. The product is then washed with a 10-20% hydrazine hydrate solution to remove the capping ligands on the surfaces of barbell nanowire heterostructures and rinsed with alcohol once before vacuum dried at room temperature. Afterwards, the clean and dried nanowire powders are hot-pressed into pellets followed by a sequential annealing at a temperature between approximately 200° C. and approximately 350° C. for two hours to eliminate any unwanted defects created during the hot press and remove any retained capping ligands.

After the fabrication process, the pellets are micro-machined into regular rectangular shape and mechanically polished before the measurement of electrical conductivity, Seebeck coefficient and thermal conductivity. The electrical conductivity is measured through a standard four-probe method with a maximum temperature fluctuation of ±2 K. The Seebeck coefficient is measured by bridging the sample between a heater and heat sink and testing the voltage difference between the hot and the cold sides with a maximum temperature fluctuation of ±0.2 K and a voltage resolution of 50 nV. The thermal conductivity (k) is measured through thermal diffusivity (α) and specific heat (Cₚ) and then calculated via the equation κ=αρCₚ (ρ is the density).

The PbTe—Bi₂Te₃ hetero structure-based nanowire composites based thermoelectric energy conversion can be used as a power generator to recover waste heat wherever a temperature difference exists, such as the exhaust gas pipes in the automobile.

In addition, the composites also can be used as thermoelectric refrigerator. Compared to the conventional compressor-based devices available today, such as the heat power generator and refrigerator, the thermoelectric devices stand out for their stability and reliability as no moving media is involved in the process of electricity generation and cooling. For example, the composites can be used in cooling central processing unit (CPU), cooling laser gun and the portable refrigerator.

The approach of synthesizing PbTe—Bi₂Te₃ heterostructure-based nanowire is a one-pot three step solution-phase reaction which is easy to be scaled up compared to other methods of making heterostructure such as molecule beam epitaxy. The solution-phase reaction happens at a much lower temperature, for example between approximately 120° C. and approximately 160° C. with a solution-phase reaction temperature near approximately 160° C. producing a better result, compared to other methods of synthesizing PbTe and Bi₂Te₃ which involve high-temperature solid-state reaction, such as zone melting and Bridgman method, which is extremely energy intensive. The bottom-up approach we are using to make nanopowder has a much better control on sizes and uniformity of the nanoparticles compared to top-down approach, such as ball milling. More importantly, through making the PbTe—Bi₂Te₃ nanocomposite, we obtained largely reduced thermal conductivity compared the bulk PbTe and Bi₂Te₃. Plus the fairly high power factor, an enhanced thermoelectric figure of merit (ZT) of 1.2 at 620K was obtained which is higher than the average ZT (around 1) of commercialized thermoelectric materials.

To generate Te—PbTe hetero structure nanowire structures, a Pb precursor solution is prepared by dissolving Pb(CH₃COO)₂3H₂O or Pb(NO₃)₂3H₂O into 1-3 ml ethylene glycol. The molar ratio between Pb(CH₃COO)₂3H₂O or Pb(NO₃)3H₂O and TeO₂, for the synthesis of Te nanowire structures is preferably less than 1. To synthesize Te—PbTe dumbbell-like hetero structure nanowire structures, the Pb precursor solution is injected to the Te nanowire solution at 100-180° C., followed by the addition of another 0.2-1 ml hydrazine solution with the concentration of 24-80%. After about 20 minutes, the Te—PbTe dumbbell-like heterostructure nanowire structures can be obtained.

Referring to FIGS. 6A and 6B are TEM images of tellurium-lead telluride dumbbell-like heterostructure nanowire structures at different magnifications (A at 200 nm and B at 50 nm) are depicted. As can be seen, the dumbbell-like structures include Te nanowire structures with two PbTe octahedral structures selectively grown at both ends of the nanowire structures. The diameter and length of the Te nanowire are about the same as the synthesized Te nanowire structures and the edge length of PbTe octahedral structures are about 65 nm as estimated from the TEM images. Referring to FIG. 7 an X-ray diffraction pattern of the synthesized tellurium-lead telluride dumbbell-like heterostructure nanowire structures is depicted. The X-ray diffraction pattern depicted in FIG. 7 can be readily indexed to hexagonal Te phase and cubic PbTe phase according to the JCPDS No. 79-0736 and 78-1905, respectively.

The synthesized Te—PbTe dumbbell-like structures can be further converted to cadmium telluride-lead telluride (CdTe—PbTe) and bismuth telluride-lead telluride (BiₓTe₁₋ₓ—PbTe) dumbbell-like heterostructure nanowire structures by selectively reacting the center Te nanowire portion with cadmium (Cd) or Bi precursor. For the synthesis of CdTe—PbTe dumbbell-like heterostructure nanowire structures, a Cd precursor solution can be used. The Cd precursor solution can be prepared by dissolving cadmium chloride (CdCl₂) or cadmium nitrate (Cd(NO₃)) or cadmium acetate (Cd(Ac)₂) into 1-3 ml ethylene glycol. The Cd precursor can then be injected into the solution containing the Te—PbTe dumbbell-like heterostructure nanowire structures. The molar ratio between the Cd and Te is about as 1:1 and the quantity can be calculated by subtracting those reacted with Pb precursors with the total Te precursor. For the synthesis of BiₓTe₁₋ₓ—PbTe dumbbell-like heterostructure nanowire structures, the Bi precursor solution prepared by dissolving BiCl₃ or Bi(NO₃)₃ or Bi(CH₃COO)₃ into 1-3 ml ethylene glycol.

The Bi precursor can then be injected into the solution containing Te—PbTe dumbbell-like heterostructure nanowire structures. The x content in the BiₓTe₁₋ₓ can be controlled by adjusting the quantity of the Bi precursor when preparing the Bi precursor solution. Referring to FIGS. 8A and 8B TEM images of cadmium telluride-lead telluride dumbbell-like hetero structure nanowire structures at different magnifications (A at 500 nm and B at 100 nm) are provided.

The morphology of the resulting products is quite similar to that of Te—PbTe dumbbell-like structures except that the diameter of the center CdTe part is about 30 nm, which is slightly larger than that of center Te part in the Te—PbTe dumbbell-like structure. In addition, the XRD pattern of the CdTe—PbTe resulting products is quite different from that of Te—PbTe dumbbell structure. Referring to FIG. 9 an X-ray diffraction pattern of cadmium telluride-lead telluride dumbbell-like heterostructure nanowire structures is provided. The XRD can be indexed to cubic CdTe and cubic PbTe phase according to the JCPDS card No. 75-2083 and 78-1905, indicating the formation of CdTe center part. Referring to FIGS. 10A and 10B, TEM images of bismuth telluride-lead telluride dumbbell-like heterostructure nanowire structure at different magnifications (A at 500 nm and B at 200 nm) are provided. These structures are similar to that of the CdTe—PbTe structure. Referring to FIG. 11, however, an X-ray diffraction pattern of bismuth telluride-lead telluride dumbbell-like heterostructure nanowire structures is depicted, which can be readily indexed to hexagonal PbTe phase and cubic PbTe phase according to the JCPDS card No. 72-2036 and 78-1905, which indicates the difference between CdTe—PbTe and Bi₂Te₃—PbTe and demonstrates the formation Bi 2Te3 center portion.

The PbTe and Bi2Te3 are well-suited for thermoelectric conversion at temperature close to near room temperature and 500 K, respectively. By fabricating these novel nanoscale heterostructure-based nanowire structures with the above-identified materials, both the thermal conductivity and the Seebeck coefficient, particularly the former, can be significantly optimized to enhance the thermoelectric Figure of Merit. The above-referenced solution phase synthesis is easily scalable and reproducible for large-scale deployment of thermoelectric conversion devices.

The thermal conductivity of the materials could be further reduced due to combination of the interface scattering effect and size confinement effect compared with the conventional nanowire structures. The teachings of the present disclosure can be extended to other nanowire heterostructure synthesis by changing the precursor solution to provide other tellurium-based thermoelectric materials.

To demonstrate the improved efficiency of the synthesized thermoelectric structures as compared to bulk material, thermoelectric properties of PbTe was measured. Referring to FIG. 12, a plot of electrical conductivity vs. temperature for lead telluride nanowire bulk sample compressed by spark plasma sintering is depicted. As can be seen from FIG. 12, the electrical conductivity of the sample is about 7714 S/m at 300 K. The electrical conductivity first decreases with increases in temperature until about 460 K reaching a minimum value of 4126 S/m. The electrical conductivity then increases with increases in temperature. Compared with that of bulk sample, the electrical conductivity of the synthesized PbTe nanowire bulk sample is much lower, about one fourth of that of bulk sample.

The Seebeck coefficient is largely enhanced compared with that of bulk sample, about 2 to 4 times higher than that of bulk sample. Referring to FIG. 13, a plot of Seebeck coefficient for lead telluride nanowire bulk sample compressed by plasma sintering is depicted. The thermal conductivity of the sample through a phonon acoustic based method was also measured. Referring to FIG. 14, a plot of Scaled amplitude vs. frequency at room temperature for lead telluride nanowire bulk sample compressed by spark plasma sintering is depicted. FIG. 14 depicts the curves of experimental and fitting data for PbTe nanowire bulk sample at room temperature, giving a total thermal conductivity value of about 1 Wm⁻¹ K⁻¹, which is around 2 times lower than bulk or other data reported in the prior art. A series of figure of merit (ZT) values were calculated and plotted versus temperature. Referring to FIG. 15 a plot of thermoelectric figure of merit (ZT) vs. temperature is depicted for various samples. For the sample providing the best ZT, the ZT value reached 2.03, which is higher as compared with previously reported values of ZT in the prior art.

Those skilled in the art will recognize that numerous modifications can be made to the specific implementations described above. Therefore, the following claims are not to be limited to the specific embodiments illustrated and described above. The claims, as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others.

What is claimed is:

1. A nano scale hetero structure tellurium-based nanowire structure, comprising:
a dumbbell-like crystalline heterostructure having a center rod-like portion and one octahedral structure connected to each end of each of the center rod-like portions, wherein the center rod-like portion is a bismuth-telluride nanowire structure and the octahedral structures are lead telluride.

2. A nanoscale heterostructure tellurium-based nanowire structure of claim 1, wherein the center rod-like portion is defined by a diameter of about 20 nm.

3. The nano scale hetero structure tellurium-based nanowire structure of claim 1, wherein the center-rod like portion is prepared by a process comprising the step of:
injecting bismuth nitrate penta-hydrate into an ethylene glycol precursor solution containing tellurium based nanowire structure.

4. The nano scale hetero structure tellurium-based nanowire structure of claim 3, wherein the dumbbell-like crystalline structure is prepared by a process comprising the steps of:
preparing a lead precursor solution; and
injecting the lead precursor solution into the ethylene glycol precursor solution containing the tellurium-based nanowire structures.

5. The nano scale hetero structure tellurium-based nanowire structure of claim 4, wherein the lead precursor is prepared by dissolving one of Pb(CH₃COO)₂3H₂O and Pb(NO₃)₂3H₂O into ethylene glycol.

6. The nano scale hetero structure tellurium-based nanowire structure of claim 3, wherein the ethylene glycol precursor solution containing tellurium-based nanowire structures is prepared by a process comprising the steps of:
mixing an amount of polyvinylpyrrolidone, an amount of an alkali, and an amount of one of tellurium dioxide and telluride salt to generate a first solution;
dissolving the first solution in ethylene glycol to generate a second mixture;
heating the second mixture; and
mixing an amount of hydrazine hydrate with the second mixture to generate the ethylene glycol precursor solution.

7. The nano scale hetero structure tellurium-based nanowire structure of claim 5, wherein a molar ratio between one of Pb(CH₃COO)₂3H₂O and Pb(NO₃)₂3H₂O and tellurium dioxide is less than 1.
